(19) United States
(12) Patent Application Publication
(10) Pub. No.: US 2018/0198560 A1
(43) Pub. Date: Jul. 12, 2018

(54) GENERALIZED POLAR CODE BASED ON POLARIZATION OF LINEAR BLOCK CODES AND CONVOLUTIONAL CODES

(71) Applicant: QUALCOMM Incorporated, San Diego, CA (US)

(72) Inventors: Jing Jiang, San Diego, CA (US); Yang Yang, San Diego, CA (US); Gabi Sarkis, San Diego, CA (US); Joseph Binamira Soriaga, San Diego, CA (US); John Edward Smee, San Diego, CA (US)

(21) Appl. No.: 15/865,170

(22) Filed: Jan. 8, 2018

Related U.S. Application Data
(60) Provisional application No. 62/444,282, filed on Jan. 9, 2017.

(51) Int. Cl. H04L 1/00; H03M 13/09; H04L 1/18

(52) U.S. Cl. CPC H04L 1/0064; H04L 1/1812; H03M 13/09

(57) ABSTRACT

Aspects of the disclosure relate to a channel coding and decoding algorithm that provides for generalized polar codes, including the concatenation of a plurality of component codes via one-step polarization. In a further aspect, selection of suitable component codes in this scheme can result in a generalized polar code having a cyclic shift property, such that information can be implicitly communicated according to the magnitude of the cyclic shift. In yet another aspect, a decoding algorithm provides for reliable decoding of such generalized polar codes, including exploitation of time diversity in sequential transmissions. Other aspects, embodiments, and features are also claimed and described.

### PRIORITY CLAIM

This application claims priority to and the benefit of provisional patent application No. 62/444,282, filed in the United States Patent and Trademark Office on Jan. 9, 2017, the entire content of which is incorporated herein by reference as if fully set forth below in its entirety and for all applicable purposes.

### TECHNICAL FIELD

The technology discussed below relates generally to wireless communication systems, and more particularly, to channel coding utilizing polar codes. Embodiments can provide and enable techniques for concatenating a plurality of codes to generate a generalized polar code.

### INTRODUCTION

Block codes, or error correcting codes are frequently used to provide reliable transmission of digital messages over noisy channels. In a typical block code, an information message or sequence is split up into blocks, and an encoder at the transmitting device then mathematically adds redundancy to the information message. Exploitation of this redundancy in the encoded information message is the key to reliability of the message, enabling correction for any bit errors that may occur due to the noise. That is, a decoder at the receiving device can take advantage of the redundancy to reliably recover the information message even though bit errors may occur, in part, due to the addition of noise to the channel.

A relatively new category of linear block error correcting codes called polar codes has recently gained interest in the field. In general terms, polar codes utilize channel polarization, where a mediocre communication channel is turned into a series of good channels and essentially useless channels. This operation transforms an information block or data word into a code word over certain sub-channels. Due to the nature of channel polarization, some of the sub-channels will transmit bits with higher reliability than other sub-channels.

As the demand for mobile broadband access continues to increase, research and development continue to advance wireless communication technologies not only to meet the growing demand for mobile broadband access, but to advance and enhance the user experience with mobile communications. Current proposals for next-generation wireless communication networks contemplate the use of much higher frequencies, in the millimeter-wave (mmW) range (e.g., above 24 GHz). As those of ordinary skill in the art well know, such mmW transmissions may be highly directional in nature, and the use of beamforming with antenna arrays to direct communication links between endpoints is being studied.

### BRIEF SUMMARY OF SOME EXAMPLES

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one example, a channel coding algorithm provides for the development of generalized polar codes, including the concatenation of a plurality of component codes via one-step polarization. In a further example, selection of suitable component codes in this scheme can result in a generalized polar code having a cyclic shift property, such that information such as a beam index can be embedded within the cyclic shift.

In another example, a decoding algorithm provides for reliable decoding of such generalized polar codes, including exploitation of time diversity in sequential transmissions.

In another example, a method of wireless communication is disclosed. The method includes generating an upper code by encoding an upper input sequence utilizing an upper encoder, and generating a lower code by encoding a lower input sequence utilizing a lower encoder. The lower encoder is configured to utilize a different coding algorithm than the upper encoder. The method further includes concatenating the upper code and the lower code utilizing a one-step polarization code to generate a first encoded message, and transmitting the first encoded message.

In still another example, a method of wireless communication is disclosed. The method includes receiving a first encoded message, which includes a first upper code and a first lower code concatenated utilizing a one-step polarization code. The method further includes demodulating symbols of the first encoded message to determine a respective log-likelihood ratio (LLR) for each of a plurality of bits of the first encoded message, determining LLRs of bits of the first upper code based on the LLRs for the plurality of bits of the first encoded message, decoding the first upper code based on the LLRs of the bits of the first upper code to determine an estimated first upper input sequence, determining the bits of the first upper code by encoding the first upper input sequence, determining LLRs of bits of the first lower code based on the LLRs for the plurality of bits of the first encoded message and the determined bits of the first upper code, and decoding the first lower code based on the LLRs of the bits of the first lower code to determine an estimated first lower input sequence.

In another example, an apparatus configured for wireless communication is disclosed. The apparatus includes a processor, a memory communicatively coupled to the processor, and a transceiver communicatively coupled to the processor. The transceiver is configured to receive a first encoded message comprising a first upper code and a first lower code concatenated utilizing a one-step polarization code. Further, the processor is configured to demodulate symbols of the first encoded message to determine a respective log-likelihood ratio (LLR) for each of a plurality of bits of the first encoded message, to determine LLRs of bits of the first upper code based on the LLRs for the plurality of bits of the first encoded message, to decode the first upper code based on the LLRs of the bits of the first upper code to determine an estimated first upper input sequence, to determine the bits of the first upper code by encoding the first upper input sequence, to determine LLRs of bits of the first lower code based on the LLRs for the plurality of bits of the first encoded message and the determined bits of the first upper code, and to decode the first lower code based on the LLRs of the bits of the first lower code to determine an estimated first lower input sequence.

In another example, an encoding apparatus is disclosed. The encoding apparatus includes a repetition encoder configured for generating a repetition code based on one or more first input bits, and a tail biting convolutional encoder configured for generating a lower code based on one or more second input bits. An input information sequence may include the one or more first input bits concatenated with the one or more second input bits. The encoding apparatus further includes a one-step polarization encoder circuit configured for concatenating a bitwise logical combination of the repetition code and the lower code, with the lower code.

These and other aspects of the invention will become more fully understood upon a review of the detailed description, which follows. Other aspects, features, and embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 is a block diagram illustrating an example of a wireless communication system.

FIG. 2 is a schematic diagram illustrating an example of a radio access network.

FIG. 3 is a block diagram illustrating an example of a hardware implementation for a scheduling entity employing a processing system.

FIG. 4 is a block diagram illustrating an example of a hardware implementation for a scheduled entity employing a processing system.

FIG. 5 is a schematic diagram illustrating wireless communication utilizing block codes.

FIG. 6 is a schematic diagram illustrating a portion of an encoder utilizing one-step polarization to concatenate component codes into a generalized polar code according to an aspect of the disclosure.

FIG. 7 is a flow chart illustrating a process for decoding a generalized polar code according to an aspect of the disclosure.

FIG. 8 is a schematic diagram illustrating additional detail of a generalized polar code to show the decoding process of FIG. 7.

FIG. 9 is a schematic diagram illustrating a portion of an encoder utilizing a repetition code to employ a cyclic shift property of a generalized polar code according to an aspect of the disclosure.

FIG. 10 is a schematic diagram illustrating beam sweeping according to an aspect of the disclosure.

FIG. 11 is a schematic diagram illustrating a decoding process for combining a plurality of transmissions of generalized polar codes having a cyclic shift property according to an aspect of the disclosure.

FIG. 12 is a flow chart illustrating additional detail of the decoding process of FIG. 11.

FIG. 13 is a schematic diagram illustrating a portion of an encoder utilizing a cyclic-shift-based encoder to embed a transmission index in sequential transmissions of generalized polar codes according to an aspect of the disclosure.

FIG. 14 is a schematic diagram illustrating a decoding process for combining a plurality of sequential transmissions of generalized polar codes according to an aspect of the disclosure.

FIG. 15 is a flow chart illustrating additional detail of the decoding process of FIG. 14.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While aspects and embodiments are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, embodiments and/or uses may come about via integrated chip embodiments and other non-module-component based devices (e.g., end-user devices, vehicles, communication devices, computing devices, industrial equipment, retail/purchasing devices, medical devices, AI-enabled devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or OEM devices or systems incorporating one or more aspects of the described innovations. In some practical settings, devices incorporating described aspects and features may also necessarily include additional components and features for implementation and practice of claimed and described embodiments. For example, transmission and reception of wireless signals necessarily includes a number of components for analog and digital purposes (e.g., hardware components including antenna, RF-chains, power amplifiers, modulators, buffer, processor(s), interleavers, adders/summers, etc.). It is intended that innovations described herein may be practiced in a wide variety of devices, chip-level components, systems, distributed arrangements, end-user devices, etc. of varying sizes, shapes and constitution.

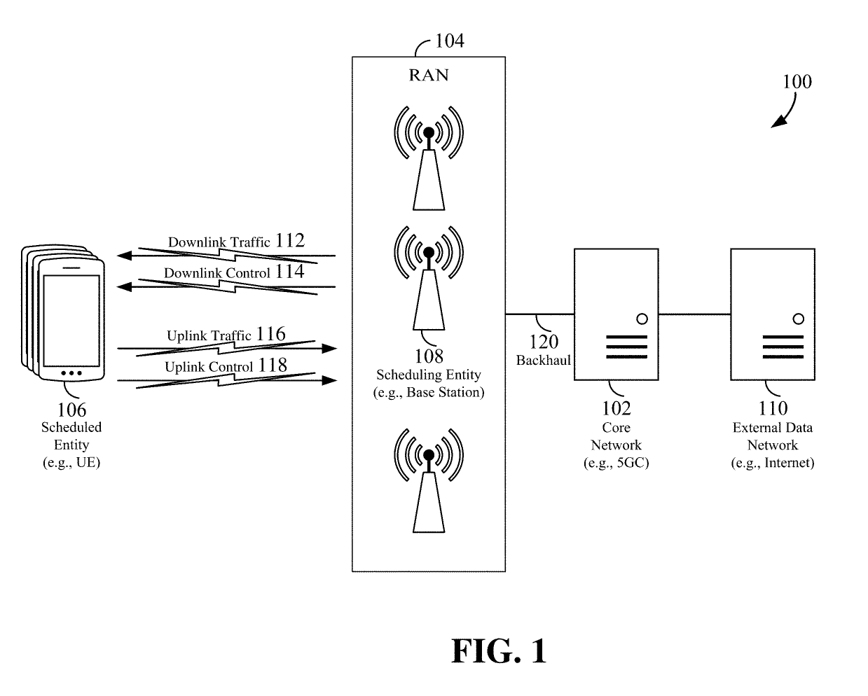

The various concepts presented throughout this disclosure may be implemented across a broad variety of telecommunication systems, network architectures, and communication standards. Referring now to FIG. 1, as an illustrative example without limitation, various aspects of the present disclosure are illustrated with reference to a wireless communication system 100. The wireless communication system 100 includes three interacting domains: a core network 102, a radio access network (RAN) 104, and a user equipment (UE) 106. By virtue of the wireless communication system 100, the UE 106 may be enabled to carry out data communication with an external data network 110, such as (but not limited to) the Internet.

The RAN 104 may implement any suitable wireless communication technology or technologies to provide radio access to the UE 106. As one example, the RAN 104 may operate according to 3^{rd} Generation Partnership Project (3GPP) New Radio (NR) specifications, often referred to as 5G. As another example, the RAN 104 may operate under a hybrid of 5G NR and Evolved Universal Terrestrial Radio Access Network (eUTRAN) standards, often referred to as LTE. The 3GPP refers to this hybrid RAN as a next-generation RAN, or NG-RAN. Of course, many other examples may be utilized within the scope of the present disclosure.

As illustrated, the RAN 104 includes a plurality of base stations 108. Broadly, a base station is a network element in a radio access network responsible for radio transmission and reception in one or more cells to or from a UE. In different technologies, standards, or contexts, a base station may variously be referred to by those skilled in the art as a base transceiver station (BTS), a radio base station, a radio transceiver, a transceiver function, a basic service set (BSS), an extended service set (ESS), an access point (AP), a Node B (NB), an eNode B (eNB), a gNode B (gNB), or some other suitable terminology.

The radio access network 104 is further illustrated supporting wireless communication for multiple mobile apparatuses. A mobile apparatus may be referred to as user equipment (UE) in 3GPP standards, but may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. A UE may be an apparatus that provides a user with access to network services.

Within the present document, a “mobile” apparatus need not necessarily have a capability to move, and may be stationary. The term mobile apparatus or mobile device broadly refers to a diverse array of devices and technologies. UEs may include a number of hardware structural components sized, shaped, and arranged to help in communication; such components can include antennas, antenna arrays, RF chains, amplifiers, one or more processors, etc. electrically coupled to each other. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an “Internet of things” (IoT). A mobile apparatus may additionally be an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A mobile apparatus may additionally be a digital home or smart home device such as a home audio, video, and/or multimedia device, an appliance, a vending machine, intelligent lighting, a home security system, a smart meter, etc. A mobile apparatus may additionally be a smart energy device, a security device, a solar panel or solar array, a municipal infrastructure device controlling electric power (e.g., a smart grid), lighting, water, etc.; an industrial automation and enterprise device; a logistics controller; agricultural equipment; military defense equipment, vehicles, aircraft, ships, and weaponry, etc. Still further, a mobile apparatus may provide for connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service data, and/or relevant QoS for transport of critical service data.

Wireless communication between a RAN 104 and a UE 106 may be described as utilizing an air interface. Transmissions over the air interface from a base station (e.g., base station 108) to one or more UEs (e.g., UE 106) may be referred to as downlink (DL) transmission. In accordance with certain aspects of the present disclosure, the term downlink may refer to a point-to-multipoint transmission originating at a scheduling entity (described further below; e.g., base station 108). Another way to describe this scheme may be to use the term broadcast channel multiplexing. Transmissions from a UE (e.g., UE 106) to a base station (e.g., base station 108) may be referred to as uplink (UL) transmissions. In accordance with further aspects of the present disclosure, the term uplink may refer to a point-to-point transmission originating at a scheduled entity (described further below; e.g., UE 106).

In some examples, access to the air interface may be scheduled, wherein a scheduling entity (e.g., a base station 108) allocates resources for communication among some or all devices and equipment within its service area or cell. Within the present disclosure, as discussed further below, the scheduling entity may be responsible for scheduling, assigning, reconfiguring, and releasing resources for one or more scheduled entities. That is, for scheduled communication, UEs 106, which may be scheduled entities, may utilize resources allocated by the scheduling entity 108.

Base stations 108 are not the only entities that may function as scheduling entities. That is, in some examples, a UE may function as a scheduling entity, scheduling resources for one or more scheduled entities (e.g., one or more other UEs).

As illustrated in FIG. 1, a scheduling entity 108 may broadcast downlink traffic 112 to one or more scheduled entities 106. Broadly, the scheduling entity 108 is a node or device responsible for scheduling traffic in a wireless communication network, including the downlink traffic 112 and, in some examples, uplink traffic 116 from one or more scheduled entities 106 to the scheduling entity 108. On the other hand, the scheduled entity 106 is a node or device that receives downlink control information 114, including but not limited to scheduling information (e.g., a grant), synchronization or timing information, or other control information from another entity in the wireless communication network such as the scheduling entity 108.

In general, base stations 108 may include a backhaul interface for communication with a backhaul portion 120 of the wireless communication system. The backhaul 120 may provide a link between a base station 108 and the core network 102. Further, in some examples, a backhaul network may provide interconnection between the respective base stations 108. Various types of backhaul interfaces may be employed, such as a direct physical connection, a virtual network, or the like using any suitable transport network.

The core network 102 may be a part of the wireless communication system 100, and may be independent of the radio access technology used in the RAN 104. In some examples, the core network 102 may be configured according to 5G standards (e.g., 5GC). In other examples, the core network 102 may be configured according to a 4G evolved packet core (EPC), or any other suitable standard or configuration.

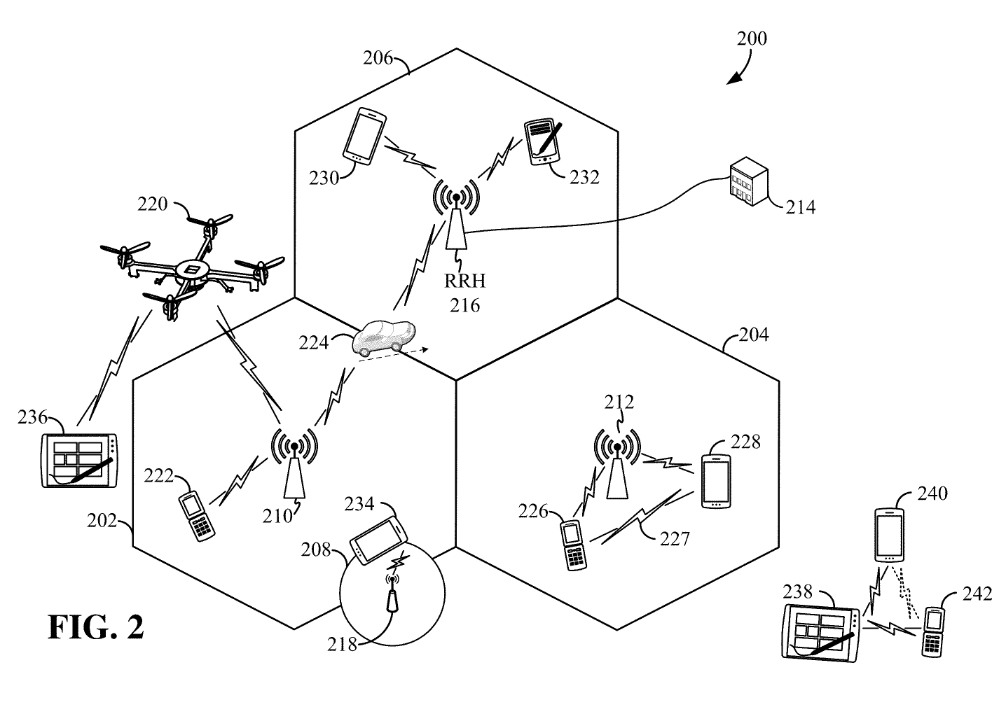

Referring now to FIG. 2, by way of example and without limitation, a schematic illustration of a RAN 200 is provided. In some examples, the RAN 200 may be the same as the RAN 104 described above and illustrated in FIG. 1. The geographic area covered by the RAN 200 may be divided into cellular regions (cells) that can be uniquely identified by a user equipment (UE) based on an identification broadcasted from one access point or base station. FIG. 2 illustrates macrocells 202, 204, and 206, and a small cell 208, each of which may include one or more sectors (not shown). A sector is a sub-area of a cell. All sectors within one cell are served by the same base station. A radio link within a sector can be identified by a single logical identification belonging to that sector. In a cell that is divided into sectors, the multiple sectors within a cell can be formed by groups of antennas with each antenna responsible for communication with UEs in a portion of the cell.

In FIG. 2, two base stations 210 and 212 are shown in cells 202 and 204; and a third base station 214 is shown controlling a remote radio head (RRH) 216 in cell 206. That is, a base station can have an integrated antenna or can be connected to an antenna or RRH by feeder cables. In the illustrated example, the cells 202, 204, and 126 may be referred to as macrocells, as the base stations 210, 212, and 214 support cells having a large size. Further, a base station 218 is shown in the small cell 208 (e.g., a microcell, picocell, femtocell, home base station, home Node B, home eNode B, etc.) which may overlap with one or more macrocells. In this example, the cell 208 may be referred to as a small cell, as the base station 218 supports a cell having a relatively small size. Cell sizing can be done according to system design as well as component constraints.

It is to be understood that the radio access network 200 may include any number of wireless base stations and cells. Further, a relay node may be deployed to extend the size or coverage area of a given cell. The base stations 210, 212, 214, 218 provide wireless access points to a core network for any number of mobile apparatuses. In some examples, the base stations 210, 212, 214, and/or 218 may be the same as the base station/scheduling entity 108 described above and illustrated in FIG. 1.

FIG. 2 further includes a quadcopter or drone 220, which may be configured to function as a base station. That is, in some examples, a cell may not necessarily be stationary, and the geographic area of the cell may move according to the location of a mobile base station such as the quadcopter 220.

Within the RAN 200, the cells may include UEs that may be in communication with one or more sectors of each cell. Further, each base station 210, 212, 214, 218, and 220 may be configured to provide an access point to a core network 102 (see FIG. 1) for all the UEs in the respective cells. For example, UEs 222 and 224 may be in communication with base station 210; UEs 226 and 228 may be in communication with base station 212; UEs 230 and 232 may be in communication with base station 214 by way of RRH 216; UE 234 may be in communication with base station 218; and UE 236 may be in communication with mobile base station 220. In some examples, the UEs 222, 224, 226, 228, 230, 232, 234, 236, 238, 240, and/or 242 may be the same as the UE/scheduled entity 106 described above and illustrated in FIG. 1.

In some examples, a mobile network node (e.g., quadcopter 220) may be configured to function as a UE. For example, the quadcopter 220 may operate within cell 202 by communicating with base station 210.

In a further aspect of the RAN 200, sidelink signals may be used between UEs without necessarily relying on scheduling or control information from a base station. For example, two or more UEs (e.g., UEs 226 and 228) may communicate with each other using peer to peer (P2P) or sidelink signals 227 without relaying that communication through a base station (e.g., base station 212). In a further example, UE 238 is illustrated communicating with UEs 240 and 242. Here, the UE 238 may function as a scheduling entity or a primary sidelink device, and UEs 240 and 242 may function as a scheduled entity or a non-primary (e.g., secondary) sidelink device. In still another example, a UE may function as a scheduling entity in a device-to-device (D2D), peer-to-peer (P2P), or vehicle-to-vehicle (V2V) network, and/or in a mesh network. In a mesh network example, UEs 240 and 242 may optionally communicate directly with one another in addition to communicating with the scheduling entity 238. Thus, in a wireless communication system with scheduled access to time-frequency resources and having a cellular configuration, a P2P configuration, or a mesh configuration, a scheduling entity and one or more scheduled entities may communicate utilizing the scheduled resources.

The air interface in the radio access network 200 may utilize one or more duplexing algorithms Duplex refers to a point-to-point communication link where both endpoints can communicate with one another in both directions. Full duplex means both endpoints can simultaneously communicate with one another. Half duplex means only one endpoint can send information to the other at a time. In a wireless link, a full duplex channel generally relies on physical isolation of a transmitter and receiver, and suitable interference cancellation technologies. Full duplex emulation is frequently implemented for wireless links by utilizing frequency division duplex (FDD) or time division duplex (TDD). In FDD, transmissions in different directions operate at different carrier frequencies. In TDD, transmissions in different directions on a given channel are separated from one another using time division multiplexing. That is, at some times the channel is dedicated for transmissions in one direction, while at other times the channel is dedicated for transmissions in the other direction, where the direction may change very rapidly, e.g., several times per slot.

The air interface in the radio access network 200 may utilize one or more multiplexing and multiple access algorithms to enable simultaneous communication of the various devices. For example, 5G NR specifications provide multiple access for UL transmissions from UEs 222 and 224 to base station 210, and for multiplexing for DL transmissions from base station 210 to one or more UEs 222 and 224, utilizing orthogonal frequency division multiplexing (OFDM) with a cyclic prefix (CP). In addition, for UL transmissions, 5G NR specifications provide support for discrete Fourier transform-spread-OFDM (DFT-s-OFDM) with a CP (also referred to as single-carrier FDMA (SC-FDMA)). However, within the scope of the present disclosure, multiplexing and multiple access are not limited to the above schemes, and may be provided utilizing time division multiple access (TDMA), code division multiple access (CDMA), frequency division multiple access (FDMA), sparse code multiple access (SCMA), resource spread multiple access (RSMA), or other suitable multiple access schemes. Further, multiplexing DL transmissions from the base station 210 to UEs 222 and 224 may be provided utilizing time division multiplexing (TDM), code division multiplexing (CDM), frequency division multiplexing (FDM), orthogonal frequency division multiplexing (OFDM), sparse code multiplexing (SCM), or other suitable multiplexing schemes.

Within the present disclosure, a frame may refer to a duration of 10 ms for wireless transmissions, with each frame consisting of 10 subframes of 1 ms each. Each 1 ms subframe may consist of one or more adjacent slots. In some examples, a slot may be defined according to a specified number of OFDM symbols with a given cyclic prefix (CP) length. For example, a slot may include 7 or 14 OFDM symbols with a nominal CP. Additional examples may include mini-slots having a shorter duration (e.g., one or two OFDM symbols). These mini-slots may in some cases be transmitted occupying resources scheduled for ongoing slot transmissions for the same or for different UEs.

In a DL transmission, the transmitting device (e.g., the scheduling entity 108) may allocate resources on the wireless channel to carry DL control information (DCI) 114. This DCI may include one or more DL control channels or signals, such as a physical broadcast channel (PBCH); a primary synchronization signal (PSS); a secondary synchronization signal (SSS); a physical control format indicator channel (PCFICH); a physical hybrid automatic repeat request (HARQ) indicator channel (PHICH); and/or a physical downlink control channel (PDCCH), etc., to one or more scheduled entities 106.

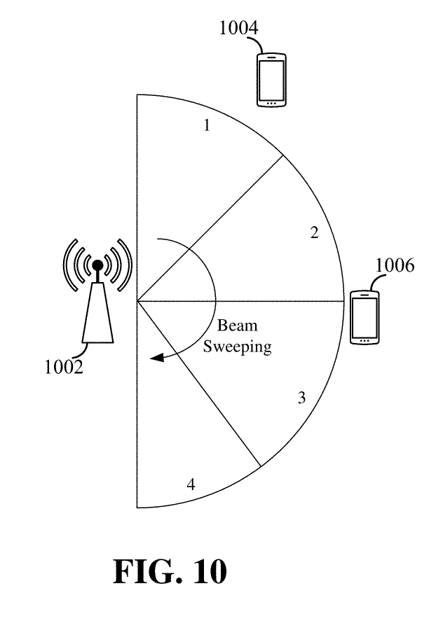

The synchronization signals PSS and SSS (collectively referred to as SS), and the PBCH, may be transmitted in an SS/PBCH block. Base stations may broadcast the SS/PBCH block over their respective cells, such that UEs within the respective cell may derive information such as carrier frequency, slot timing, and other broadcast information. As described further below (see FIG. 10), in some examples corresponding to directional radio communication such as millimeter wave (mmW) communications, a base station may sweep such broadcast control information across the cell, by transmitting in each one of a plurality of sectors, regions, or directions relative to the base station.

The PCFICH may provide information to assist a receiving device in receiving and decoding the PDCCH. The PDCCH may carry downlink control information (DCI) including but not limited to power control commands, scheduling information, a grant, and/or an assignment of REs for DL and UL transmissions. The PHICH may carry HARQ feedback transmissions such as an acknowledgment (ACK) or negative acknowledgment (NACK). HARQ is a technique well-known to those of ordinary skill in the art, wherein the integrity of packet transmissions may be checked at the receiving side for accuracy, e.g., utilizing any suitable integrity checking mechanism, such as a checksum or a cyclic redundancy check (CRC). If the integrity of the transmission confirmed, an ACK may be transmitted, whereas if not confirmed, a NACK may be transmitted. In response to a NACK, the transmitting device may send a HARQ retransmission, which may implement chase combining, incremental redundancy, etc.

In an UL transmission, the transmitting device (e.g., the scheduled entity 106) may utilize scheduled resources to carry UL control information 118, including one or more UL control channels such as a physical uplink control channel (PUCCH), to the scheduling entity 108. UL control information may include a variety of packet types and categories, including pilots, reference signals, and information configured to enable or assist in decoding uplink data transmissions. In some examples, the UL control information 118 may include a scheduling request (SR), i.e., request for the scheduling entity 108 to schedule uplink transmissions. Here, in response to the SR transmitted on the control channel 118, the scheduling entity 108 may transmit downlink control information 114 that may schedule resources for uplink packet transmissions. UL control information may also include HARQ feedback, channel state feedback (CSF), or any other suitable UL control information.

In addition to control information, resources on the wireless channel may be allocated for user data or traffic data. Such traffic may be carried on one or more traffic channels, such as, for a DL transmission, a physical downlink shared channel (PDSCH); or for an UL transmission, a physical uplink shared channel (PUSCH). In some examples, a portion of the resources on the wireless channel may be configured to carry system information blocks (SIB s), carrying information that may enable access to a given cell.

The channels or carriers described above and illustrated in FIG. 1 are not necessarily all the channels or carriers that may be utilized between a scheduling entity 108 and scheduled entities 106, and those of ordinary skill in the art will recognize that other channels or carriers may be utilized in addition to those illustrated, such as other traffic, control, and feedback channels.

These physical channels described above are generally multiplexed and mapped to transport channels for handling at the medium access control (MAC) layer. Transport channels carry blocks of information called transport blocks (TB). The transport block size (TBS), which may correspond to a number of bits of information, may be a controlled parameter, based on the modulation and coding scheme (MCS) and the number of resource blocks (RBs) in a given transmission.

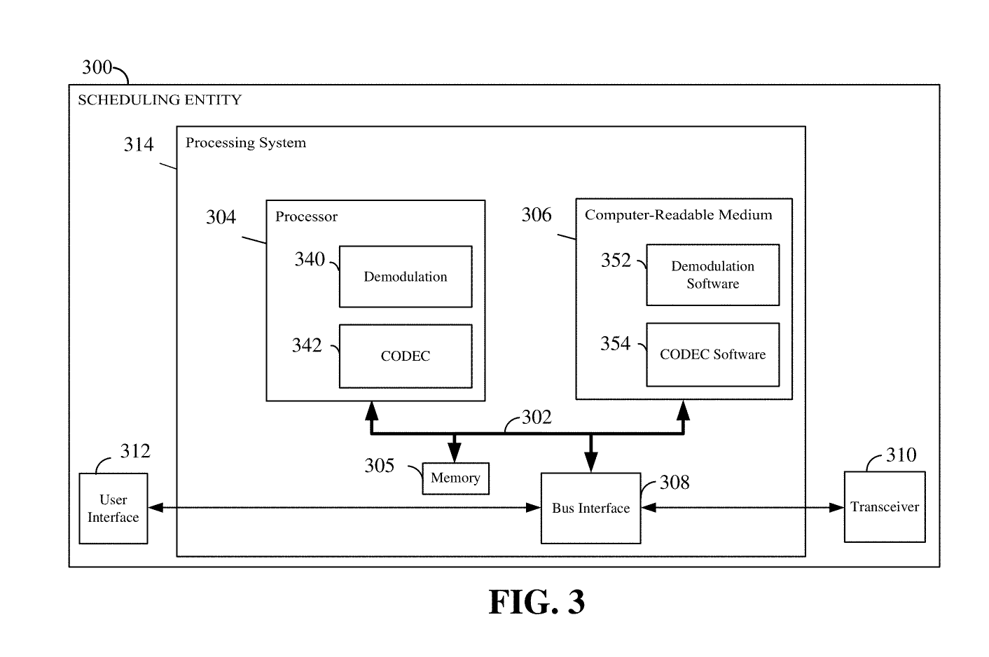

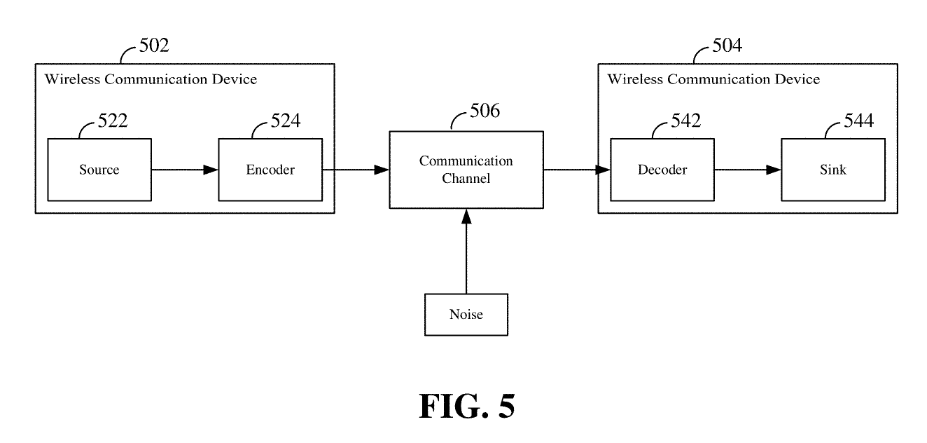

FIG. 3 is a block diagram illustrating an example of a hardware implementation for a scheduling entity 300 employing a processing system 314. For example, the scheduling entity 300 may be a user equipment (UE) as illustrated in any one or more of FIGS. 1 and/or 2. In another example, the scheduling entity 300 may be a base station as illustrated in any one or more of FIGS. 1 and/or 2. In another example, the scheduling entity may be a wireless communication device 502/504 as illustrated in FIG. 5.

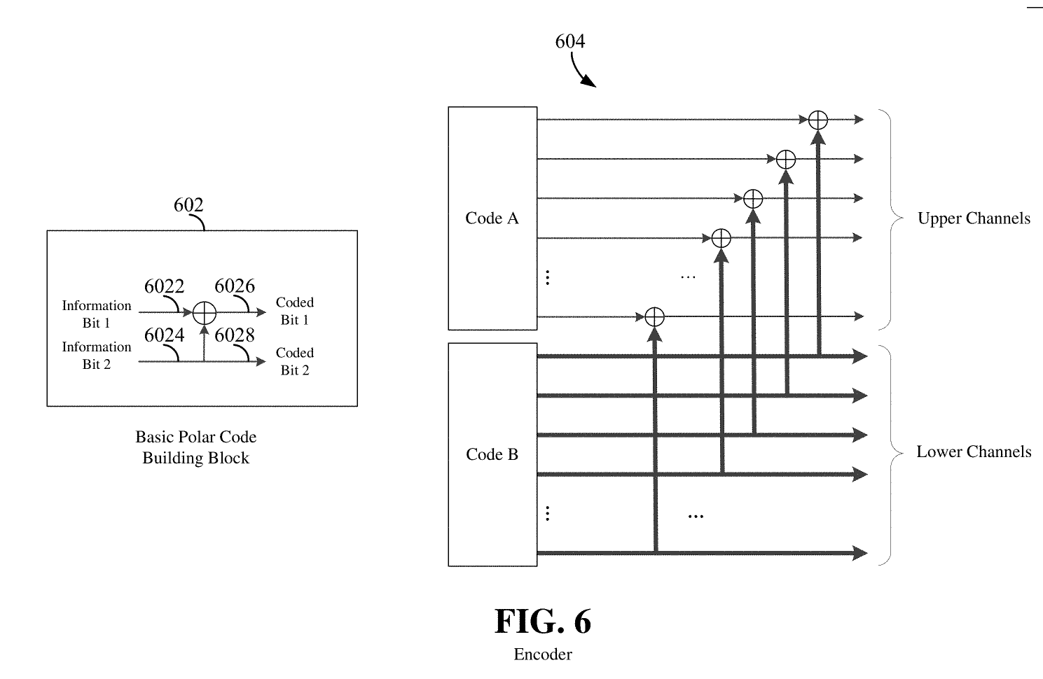

The scheduling entity 300 may be implemented with a processing system 314 that includes one or more processors 304. Examples of processors 304 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the scheduling entity 300 may be configured to perform any one or more of the functions described herein. That is, the processor 304, as utilized in a scheduling entity 300, may be used to implement any one or more of the processes and procedures described below and illustrated in FIGS. 6-15.

In this example, the processing system 314 may be implemented with a bus architecture, represented generally by the bus 302. The bus 302 may include any number of interconnecting buses and bridges depending on the specific application of the processing system 314 and the overall design constraints. The bus 302 communicatively couples together various circuits including one or more processors (represented generally by the processor 304), a memory 305, and computer-readable media (represented generally by the computer-readable medium 306). The bus 302 may also link various other circuits such as timing sources, peripherals, voltage regulators, and power management circuits, which are well known in the art, and therefore, will not be described any further. A bus interface 308 provides an interface between the bus 302 and a transceiver 310. The transceiver 310 provides a communication interface or means for communicating with various other apparatus over a transmission medium. Depending upon the nature of the apparatus, a user interface 312 (e.g., keypad, display, speaker, microphone, joystick) may also be provided.

In some aspects of the disclosure, the processor 304 may include demodulation circuitry 340 configured for various functions, including, for example, demodulating symbols of a received message to determine log-likelihood ratios (LLRs) for the bits of the received message. For example, the demodulation circuitry 340 may be configured to implement one or more of the functions described below in relation to FIGS. 6-8, 11, 12, 14, and/or 15.

The processor 304 may further include encoding/decoding (CODEC) circuitry 342 configured for various functions, including, for example, encoding an information signal utilizing any one or more coding algorithms, including but not limited to polar coding, repetition coding, tail-biting convolutional coding, cyclic shift-based coding, etc.; and/or decoding an encoded signal utilizing any one or more decoding algorithms, including but not limited to successive cancellation decoding. For example, the CODEC circuitry 342 may be configured to implement one or more of the functions described below in relation to FIGS. 6-9, and/or 11-15.

The processor 304 is responsible for managing the bus 302 and general processing, including the execution of software stored on the computer-readable medium 306. The software, when executed by the processor 304, causes the processing system 314 to perform the various functions described below for any particular apparatus. The computer-readable medium 306 and the memory 305 may also be used for storing data that is manipulated by the processor 304 when executing software.

One or more processors 304 in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium 306. The computer-readable medium 306 may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium 306 may reside in the processing system 314, external to the processing system 314, or distributed across multiple entities including the processing system 314. The computer-readable medium 306 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

In one or more examples, the computer-readable storage medium 306 may include demodulation software 352 configured for various functions, including, for example, demodulating symbols of a received message to determine log-likelihood ratios (LLRs) for the bits of the received message. For example, the demodulation software 352 may be configured to implement one or more of the functions described below in relation to FIGS. 6-8, 11, 12, 14, and/or 15.

The computer-readable storage medium 306 may further include encoding/decoding (CODEC) software 354 configured for various functions, including, for example, encoding an information signal utilizing any one or more coding algorithms, including but not limited to polar coding, repetition coding, tail-biting convolutional coding, cyclic shift-based coding, etc.; and/or decoding an encoded signal utilizing any one or more decoding algorithms, including but not limited to successive cancellation decoding. For example, the CODEC software 354 may be configured to implement one or more of the functions described below in relation to FIGS. 6-9, and/or 11-15.

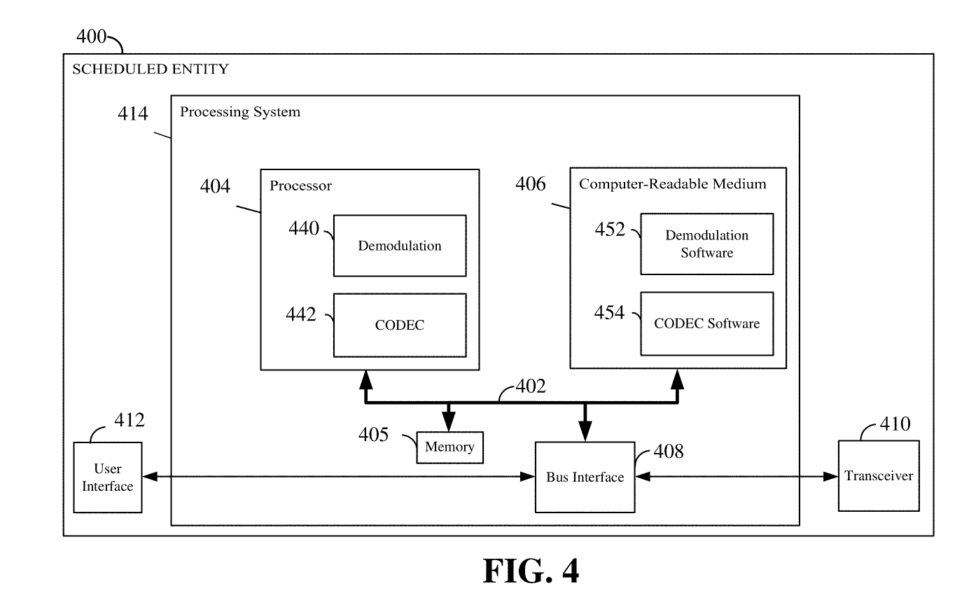

FIG. 4 is a conceptual diagram illustrating an example of a hardware implementation for an exemplary scheduled entity 400 employing a processing system 414. In accordance with various aspects of the disclosure, an element, or any portion of an element, or any combination of elements may be implemented with a processing system 414 that includes one or more processors 404. For example, the scheduled entity 400 may be a UE as illustrated in any one or more of FIGS. 1 and/or 2. In another example, the scheduled entity may be a wireless communication device 502/504 as illustrated in FIG. 5.

The processing system 414 may be substantially the same as the processing system 314 illustrated in FIG. 3, including a bus interface 408, a bus 402, memory 405, a processor 404, and a computer-readable medium 406. Furthermore, the scheduled entity 400 may include a user interface 412 and a transceiver 410 substantially similar to those described above in FIG. 3. That is, the processor 404, as utilized in a scheduled entity 400, may be used to implement any one or more of the processes described below and illustrated in FIGS. 6-15.

In some aspects of the disclosure, the processor 404 may include demodulation circuitry 440 configured for various functions, including, for example, demodulating symbols of a received message to determine log-likelihood ratios (LLRs) for the bits of the received message. For example, the demodulation circuitry 440 may be configured to implement one or more of the functions described below in relation to FIGS. 6-8, 11, 12, 14, and/or 15.

The processor 304 may further include encoding/decoding (CODEC) circuitry 442 configured for various functions, including, for example, encoding an information signal utilizing any one or more coding algorithms, including but not limited to polar coding, repetition coding, tail-biting convolutional coding, cyclic shift-based coding, etc.; and/or decoding an encoded signal utilizing any one or more decoding algorithms, including but not limited to successive cancellation decoding. For example, the CODEC circuitry 442 may be configured to implement one or more of the functions described below in relation to FIGS. 6-9, and/or 11-15.

In one or more examples, the computer-readable storage medium 406 may include encoding software 452 configured for various functions, including, for example, encoding an information signal utilizing any one or more coding algorithms, including but not limited to polar coding, repetition coding, tail-biting convolutional coding, cyclic shift-based coding, etc. For example, the encoding software 452 may be configured to implement one or more of the functions described below in relation to FIGS. 6-8, 11, 12, 14, and/or 15.

The computer-readable storage medium 406 may further include decoding software 454 configured for various functions, including, for example, decoding an encoded signal utilizing any one or more decoding algorithms, including but not limited to successive cancellation decoding. For example, the decoding software 454 may be configured to implement one or more of the functions described below in relation to FIGS. 6-9, and/or 11-15.

In one configuration for receiving and decoding a wireless transmission, an apparatus (e.g., the scheduling entity 300 and/or the scheduled entity 400) for wireless communication includes means for generating an upper code and lower code utilizing an upper encoder and lower encoder, respectively. The apparatus 300 and/or 400 may further include means for concatenating the upper code and lower code utilizing a one-step polarization code. The apparatus 300 and/or 400 may further include means for cyclically shifting the information sequence. In one aspect, the aforementioned means may be the processor(s) 304 and/or 404 shown in FIGS. 3 and 4, configured to perform the functions recited by the aforementioned means. In another aspect, the aforementioned means may be a circuit or any apparatus configured to perform the functions recited by the aforementioned means.

In another configuration for encoding and transmitting a wireless transmission, an apparatus (e.g., the scheduling entity 300 and/or the scheduled entity 400) for wireless communication includes means for demodulating symbols of an encoded message, and means for determining LLRs for each of a plurality of bits of the encoded message. The apparatus 300 and/or 400 may further include means for determining LLRs of bits of an upper code and a lower code based on the LLRs for the plurality of bits of the encoded message, i.e., decoding a one-step polarization-encoded message. The apparatus 300 and/or 400 may further include means for determining an information message by decoding the upper code and the lower code. The apparatus 300 and/or 400 may further include means for cyclically shifting the LLRs for the upper and lower codes. In one aspect, the aforementioned means may be the processor(s) 304 and/or 404 configured to perform the functions recited by the aforementioned means. In another aspect, the aforementioned means may be a circuit or any apparatus configured to perform the functions recited by the aforementioned means.

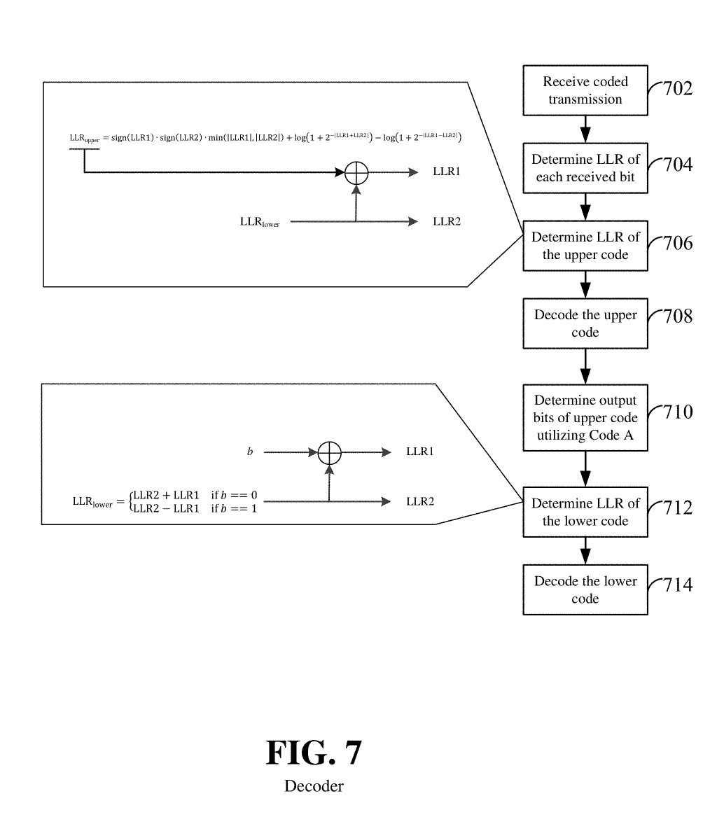

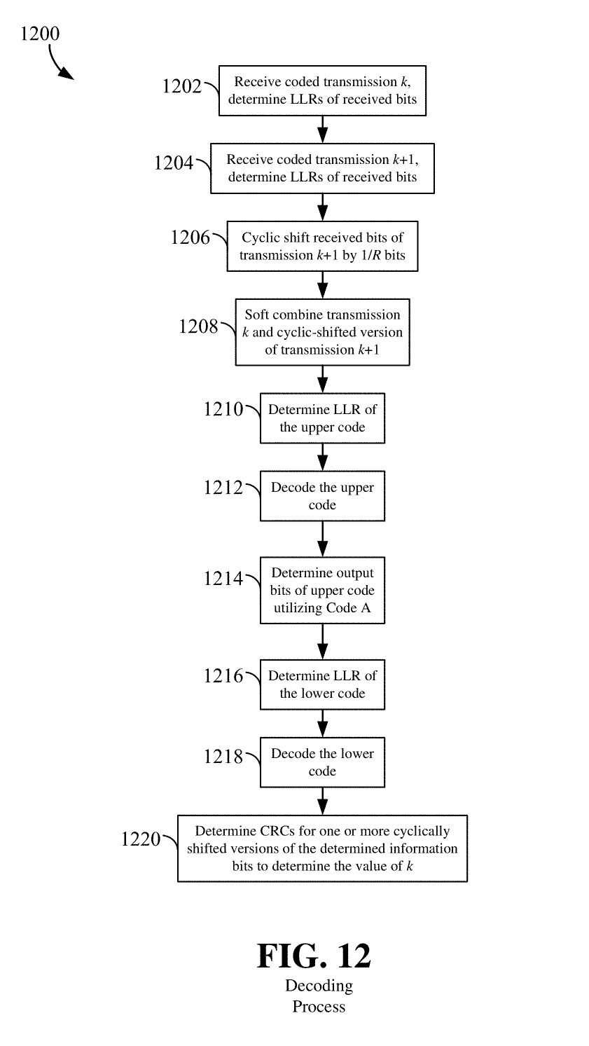

Of course, in the above examples, the circuitry included in the processors 304 and/or 404 is merely provided as an example, and other means for carrying out the described functions may be included within various aspects of the present disclosure, including but not limited to the instructions stored in the computer-readable storage medium 306 and/or 406, or any other suitable apparatus or means described in any one of the FIGS. 1-6, 8-11, 13, and/or 14, and utilizing, for example, the processes and/or algorithms described herein in relation to FIGS. 7, 12, and/or 15.

Referring now to FIG. 5, a schematic diagram illustrates wireless communication between a first wireless communication device 502 and a second wireless communication device 504. Each wireless communication device 502 and 504 may be a user equipment (UE) 106, a base station 108, a scheduled entity 400, a scheduling entity 300, or any other suitable apparatus or means for wireless communication. In the illustrated example, a source 522 within the first wireless communication device 502 transmits a digital message over a communication channel 506 (e.g., a wireless channel) to a sink 544 in the second wireless communication device 504. The source 522 and sink 544 may generally represent applications running on the respective endpoints, buffers, memory, or storage entities at the respective devices, etc.

In order for transmissions over the communication channel 506 to obtain a low block error rate (BLER) while still achieving very high data rates, channel coding may be used. That is, wireless communication may generally utilize a suitable error correcting block code.

In a typical block code, an information message or sequence is split up into blocks, each block having a length of K bits. An encoder 524 at the first (transmitting) wireless communication device 502 then mathematically adds redundancy to the information message. In an encoder (e.g., encoder 524), a coding scheme maps from information bits to coded bits, and the coded bits are sent through the communication channel 506. Each coded bit generally sees a channel that may be characterized by a signal-to-noise ratio (SNR) and certain mutual information.

By adding the redundancy to the information message, codewords result, having a length of N, where N>K. Here, the coding rate R is the ratio between the message length and the block length: i.e., R=K/N. Exploitation of this redundancy in the encoded information message is the key to reliability of the message, enabling correction for any bit errors that may occur due to the noise. That is, a decoder 542 at the second (receiving) wireless communication device 504 can take advantage of the redundancy to reliably recover the information message even though bit errors may occur, in part, due to the addition of noise to the channel.

Many examples of such error correcting block codes are known to those of ordinary skill in the art, including Hamming codes, Bose-Chaudhuri-Hocquenghem (BCH) codes, turbo codes, and low-density parity check (LDPC) codes, among others. Many existing wireless communication networks utilize such block codes, such as 3GPP LTE networks, which utilize turbo codes; and IEEE 802.11n Wi-Fi networks, which utilize LDPC codes. However, for future networks, a new category of block codes, called polar codes, presents a potential opportunity for reliable and efficient information transfer.

In early 5G NR specifications, user data is coded using quasi-cyclic LDPC. Control information and the physical broadcast channel (PBCH) are coded using polar coding, based on nested sequences. While some aspects of the present disclosure may utilize these codes, those of ordinary skill in the art will recognize that aspects of the present disclosure may be implemented utilizing any suitable channel code. Various implementations of scheduling entities 300 and scheduled entities 400 may include suitable hardware and capabilities (e.g., an encoder, a decoder, and/or a CODEC) to utilize one or more of these channel codes for wireless communication.

Polar codes are linear block error correcting codes currently known to those skilled in the art. Polar codes are the first explicit codes that achieve the channel capacity of symmetric binary-input discrete memoryless channels. That is, polar codes achieve the channel capacity (the Shannon limit) or the theoretical upper bound on the amount of error-free information that can be transmitted on a discrete memoryless channel of a given bandwidth in the presence of noise.

Polar coding generally refers to polarization of the channel seen by each of the information bits being sent. In general terms, channel polarization is generated with a recursive algorithm that defines polar codes. That is, a polar code may polarize the reliability of the bits observed on the channel, such that, from the perspective of the information bits, the channel is polarized into good channels and bad channels. In general, the good channels may be used to send information bits, and the bad channels may be used to send frozen bits, which may be predetermined values and do not necessarily include information bits. In this way, the receiving device 504 may determine the frozen bits' values without decoding the received message.

For channels sent utilizing polar codes, rate matching may be achieved utilizing, e.g., puncturing, shortening, and/or repetition.

### Encoder

FIG. 6 schematically illustrates various components of an encoder according to some aspects of the present disclosure. In the discussion that follows, a generalized polar coding algorithm is described.

As illustrated in block 602, the basic building block of a generalized polar code corresponding to a one-step polar coding algorithm may be a logical exclusive-OR (XOR) operation. In this basic building block, information bit 1, 6022 and information bit 2, 6024 may be mapped to coded bit 1, 6026, and coded bit 2, 6028. Coded bit 1, 6026 is the exclusive OR of information bit 1, 6022 and information bit 2, 6024. Coded bit 2, 6028 is the same as information bit 2, 6024.

The XOR operation polarizes the channel, causing the upper channel to be a weaker effective channel (i.e., lower reliability) compared to the lower channel Thus, from the perspective of the information bits, the lower channel (i.e., the channel seen by information bit 2, 6024) is better, or more reliable, than the upper channel (i.e., the channel seen by information bit 1, 6022). For example, if the coded bits 6026 & 6028 were transmitted through an erasure channel, then information bit 1, 6022, could only be decoded when both coded bits 6026 & 6028 were received. However, information bit 2, 6024, could be decoded as long as one of the coded bits is not erasured.

Polarization utilizing the XOR (as illustrated in the building block 602) is one example of a bitwise logical operation that may be utilized within the scope of the present disclosure. However, any suitable bitwise logical operation may be utilized without deviating from the scope of the disclosure. In another example, polarization may be accomplished utilizing real addition. In some examples, different channels may be combined at the physical layer utilizing a high order modulation (e.g., QAM).

As illustrated in the encoder 604, which includes two component codes (Code A and Code B), the basic polar code building block 602 may easily be extended to apply to plural-bit component codes. The encoder 604 includes two component codes, Code A and Code B. As illustrated in FIG. 6, by extending the basic polar code building block 602 to multiple bits, these component codes may be concatenated into a single coded message utilizing one-step polarization according to an aspect of the present disclosure. This one-step polarization utilizes the basic polar code building block illustrated at block 602 to combine bits of the different component codes and generate the single coded message by concatenating a bitwise logical combination (e.g., XOR) of the upper code and the lower code, with the lower code. The resulting coded message may be referred to as a generalized polar code. In an example where both Code A and Code B are polar codes, the combined code is a conventional polar code.

Code A and Code B may be any suitable channel code, including but not limited to a linear block code, a convolutional code, a repetition code, a cyclic-shift-based code, etc., as long as their coding rates are suitable. That is, the code rate of Code A and of Code B may be configured based on the equivalent channel through which they communicate. In the illustrated example, the bits output from the lower code (from Code B) are more reliable than the bits output from the upper code (generated based on both Code A and Code B), as described above. Accordingly, because the bits of the lower code are stronger than the bits of the upper code, a higher code rate may be utilized at the lower code (Code B), and a lower code rate may be utilized at the upper code (Code A).

### Decoder

Full decoding of a polar code is a relatively complex operation, known to those of ordinary skill in the art. Such decoders frequently employ successive cancellation (SC) decoding, although other decoding algorithms are also known. Accordingly, a full description of the decoding operations for a polar code is not described herein. Below, decoding operations that apply to the generalized, one-step polarization described above and illustrated in FIG. 6 will be described.

FIG. 7 provides a flow chart illustrating a process 700 for decoding a generalized polar code according to an aspect of the present disclosure. As described below, some or all illustrated features may be omitted in a particular implementation within the scope of the present disclosure, and some illustrated features may not be required for implementation of all embodiments. In various examples, the process 700 may be carried out by the scheduling entity 300 illustrated in FIG. 3, the scheduled entity 400 illustrated in FIG. 4, the receiving wireless communication device 504 (e.g., at the decoder 542), or at any other suitable apparatus or means for carrying out the functions or algorithm described below. For ease of description, the process that follows will be described with reference to the receiving device 504 and its decoder 542 and, when beneficial, the encoder 604 illustrated in FIG. 6. That is, to illustrate certain aspects of the disclosure, it is assumed that a received message was encoded utilizing the encoder 604 illustrated in FIG. 6, including an upper code (Code A) and a lower code (Code B).

At block 702, the receiving device 504 may receive a coded transmission, encoded utilizing a generalized polar code as described above. After receiving the transmission, at block 704, the receiving device 504 may determine a log likelihood ratio (LLR) of each received bit, including, e.g., LLR1 and LLR2. That is, when the receiving device 504 receives the coded transmission, demodulation of the received signal may result in a determined LLR corresponding to a relative certainty about whether each received bit has a value of 0 or 1. In simple terms, a received waveform may not precisely match the expected waveform for either a 0 or for a 1. However, if the waveform is closer to the expected waveform for a 1 than the waveform for a 0, then the certainty about the intended waveform, and accordingly, the LLR, may be relatively high.

Once the LLR for each of the received coded bits is determined, the LLRs for the bits output from the upper code (Code A) and lower code (Code B) may be determined by algorithmically reconstructing the encoder 604 and working backwards from determined LLRs. That is, once they are determined, the LLRs of the received bits may be utilized to determine LLRs of the outputs of the upper and lower codes. In turn, these values may be applied to decoders corresponding to the upper and lower codes to determine LLRs of the information bits.

To illustrate, block 706 includes an expanded view showing the basic polar code building block, described above and illustrated in FIG. 6. As seen here, the LLR of the output bits of the upper code (i.e., LLRᵤₚₚₑᵣ) may be determined by virtue of the XOR operation utilized in the basic polar code building block 602. Thus, at block 706, LLRᵤₚₚₑᵣ, or the LLR for one of the bits of the upper code (Code A in the example illustrated in FIG. 6) may be determined according to the following equation:

LLRᵤₚₚₑᵣ=sign(LLR1)·sign(LLR2)·min(|LLR1|,|LLR2|)+log(1+2^{-|LLR1+LLR2|})−log(1+2^{-LLR1-LLR2|})

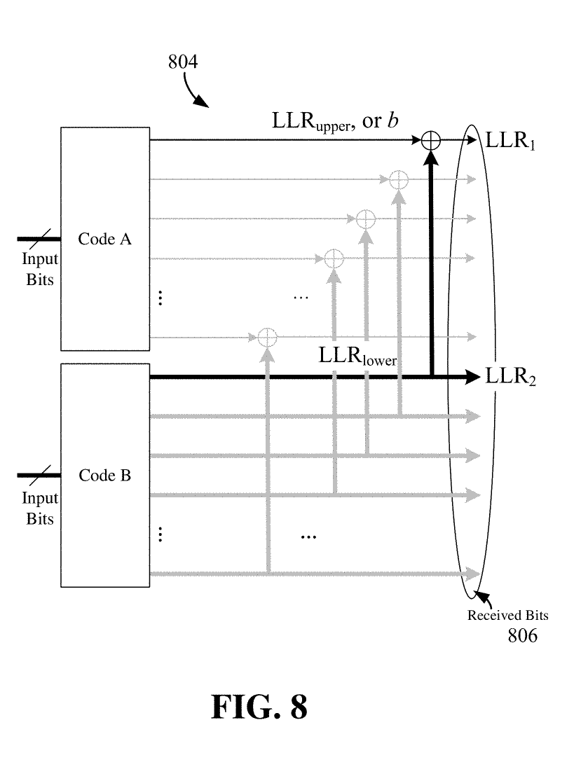

Here, LLR1 represents the determined LLR of received bit 1, and LLR2 represents the determined LLR of received bit 2, where received bits 1 and 2 are the bits corresponding to the output of the basic polar code building block. FIG. 8 illustrates these particular bit locations in a reconstruction 804 of the encoder.

While the above equation is specific to a generalized one-step polar coder that utilizes XOR logic as one example, as described above, an XOR is not the only form of logic that may be utilized in such a generalized polar coder within the scope of the present disclosure. Those of ordinary skill in the art will recognize that different equations may be utilized for different logical operations in a generalized polar coder, and will be enabled to determine the suitable equation to recover the LLRs of the upper and lower and lower codes in a straightforward manner.

By utilizing this algorithm for each of the XOR operations, the LLRs of all output bits of Code A may be calculated. Once the LLR of all output bits of Code A are determined, at block 708, the input bits of Code A may be determined by applying a decoding algorithm corresponding to the channel code utilized for Code A. As described above, Code A may correspond to any suitable block code, including but not limited to a polar code, LDPC code, turbo code, convolutional code, etc. The details of the channel coding and decoding algorithm depend on which channel code is used for Code A, and would be known to one of ordinary skill in the art.

After decoding the upper code, Code A, a hypothesis of the input bits may be obtained. At this time, optionally, the receiving device 504 may check the integrity of the decoding process, e.g., by calculating a CRC, checksum, etc., and comparing it to a corresponding received value. Such CRC, checksum, or integrity check processes are well-known in the art, and can provide better certainty as to whether there were any bit errors in the received information. In a further example, as will be understood to those of ordinary skill in the art, even if there were one or more bit errors in the received bits, the nature of the upper code, Code A, may provide for some level of error correction, such that the true value of the input bits that were input into Code A may still be determined.

Once the input bits to Code A are known, at block 710 the decoder 542 at the receiving device 504 may then determine the output bits of Code A by applying the coding algorithm utilized by Code A. That is, the decoder 542 may reproduce the coding algorithm for Code A, implemented by the encoder 524 at the transmitting device 502, to calculate the actual values of the output bits of Code A. When the output bits of the upper code are known, at block 712, the decoder 542 at the receiving device 504 may then calculate the LLRs for the output bits from the lower code (Code B). In FIG. 7, block 712 is expanded to show the basic polar code building block, described above and illustrated in FIG. 6. As seen here, the LLR of the output bits of the lower code (i.e., LLR_{lower}) may be determined by virtue of the XOR operation utilized in the basic polar code building block 602. Thus, at block 712, LLR_{lower}, or the LLR for one of the bits of the lower code (Code B in the example illustrated in FIG. 6) may be determined according to the following equation:

$${LLR}_{lower} = \{ \begin{matrix}LLR 2 + LLR 1 & if b = 0 \\ LLR 2 - LLR 1 & if b = 1\end{matrix}$$

Here, b corresponds to the determined output bit value from the upper code, Code A, and LLR1 and LLR2 correspond to the respective LLRs of the received bits determined at the demodulation stage (block 704 in this example). As indicated above, this specific equation is provided according to the exemplary generalized polar coder utilizing XOR logic, as illustrated in the basic polar code building block 602. However, those of ordinary skill in the art will recognize that other equations may apply for basic polar code building blocks utilizing different logical operations, and the specific equations for those other logical operations will be readily deduced.

When the LLR of all the output bits of Code B are determined, at block 714, the input bits of Code B may be determined by applying a decoding algorithm corresponding to the channel code utilized for Code B. As described above, Code B may correspond to any suitable block code, including but not limited to a polar code, LDPC code, turbo code, convolutional code, etc. The details of the channel coding and decoding algorithm depend on which channel code is used for Code A, and would be known to one of ordinary skill in the art.

After decoding the lower code, Code B, a hypothesis of the input bits may be obtained. At this time, optionally, the receiving device 504 may check the integrity of the decoding process, e.g., by calculating a CRC, checksum, etc., and comparing it to a corresponding received value. Such CRC, checksum, or integrity check processes are well-known in the art, and can provide better certainty as to whether there were any bit errors in the received information. In a further example, as will be understood to those of ordinary skill in the art, even if there were one or more bit errors in the received bits, the nature of the lower code, Code B, may provide for some level of error correction, such that the true value of the input bits that were input into Code B may still be determined. Once the input bits to Code B are known, in this example, the full information sequence is known, corresponding to the input bits to both the upper and lower encoders.

Exploiting the Cyclic Shift Property of Generalized Polar Codes when Component Codes Include a Linear Block Code Having a Cyclic Shift Property, and a Tail-Biting Convolutional Code

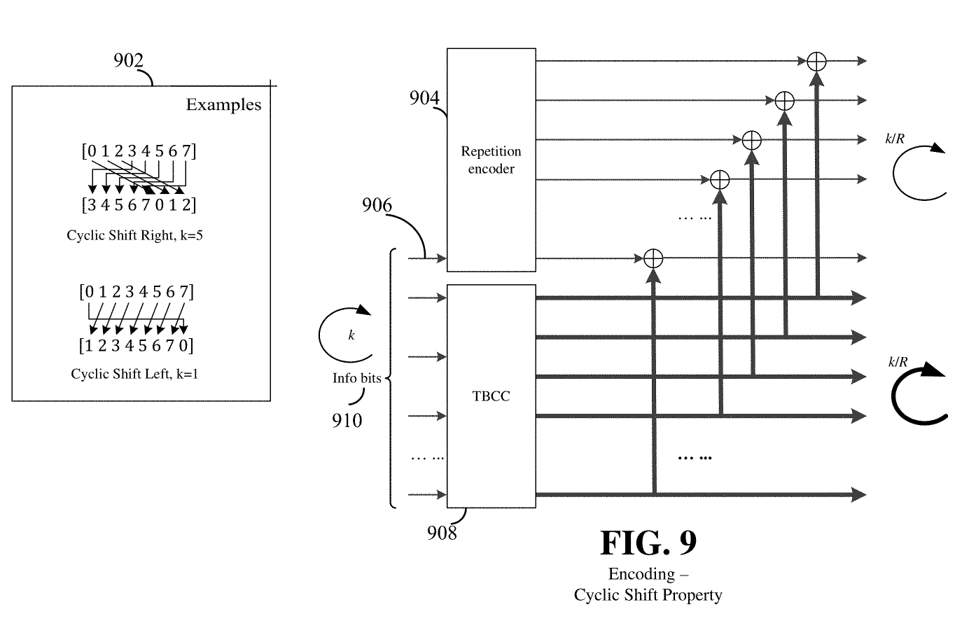

FIG. 9 illustrates one particular example of one-step polarization to concatenate a plurality of codes, in order to illustrate a further aspect of the present disclosure. In the illustrated example, the outputs of an upper code 904 and a lower code 908 are concatenated utilizing generalized polar coding, as described above. In this example, however, an input information bit sequence 910 spans the full set of input bits of the lower code 908, and overlaps with (e.g.) one bit of the upper code 904. In the illustrated example, the upper code 904 may be a repetition code based on one or more information bits. For example, information bit 906 may be repeated for each bit output from the repetition encoder 904. For example, a single-bit input of 1 may result in an output sequence of all 1s; and a single-bit input of 0 may result in an output sequence of all 0s. The upper coder 904 may utilize any other suitable repetition codes, wherein the upper information sequence input into the repetition encoder results in any suitable repeating output sequence based on its input bit or bits (e.g., 010101 . . . and 101010 . . . , etc.). In another example, if the input information 906 input into the upper code 904 includes a plurality of bits, the full input information sequence 904 may be repeated at the output of the repetition encoder 904.

In a further aspect, the lower code 908 may be a tail-biting convolutional code (TBCC). A TBCC is a terminated convolutional code known to those of ordinary skill in the art.

Further, the information bits 910 may include an upper information sequence and a lower information sequence, each including a sequence of one or more bits. In one example, the information bits may be configured such that the upper information sequence is input to the upper encoder (e.g., the repetition coder) 904, and the lower information sequence is input to the lower encoder (e.g., the TBCC coder) 908.

As in the previous examples, in FIG. 9, the output bits of the upper encoder 904 and the lower encoder 908 may be concatenated utilizing a one-step polar code. According to an aspect of the present disclosure, with this configuration where the upper code 904 is a single-information-bit repetition code and the lower code 908 is a TBCC, then the generalized code after one-step polarization exhibits a cyclic shift property.

A cyclic shift is a bitwise operation well-known to those of ordinary skill in the art, where bits of a sequence may be shifted over to the left or the right by a number of positions or indexes, k. Whenever a bit is shifted beyond one end of the sequence, that bit is moved (or rotated) to the other end of the sequence. In other words, k bits may be taken from one end of a sequence and moved to the other end of the sequence. Such a cyclic shift may at times be referred to as a circular shift, or a rotate (without a carry bit). At block 902, FIG. 9 shows two examples of cyclic shifts applied to 8-bit sequences, merely to illustrate the concept.

Here, a channel code that exhibits a cyclic shift property refers to a code wherein, if a cyclic shift is applied to the input information bit sequence, then the output bit sequence is also cyclic-shifted. For example, a cyclic shift of the information bits by k may result in a cyclic shift of the output bits by k/R, where R refers to the coding rate (number of coded bits per information bit) of the encoder having the cyclic shift property. As is known to those of ordinary skill in the art, a TBCC encoder (i.e., the lower code 908 in this example) exhibits such a cyclic shift property. That is, if the lower information sequence 910 is subjected to a cyclic shift by k, then the resulting lower coded bits are subjected to a cyclic shift by k/R. Accordingly, in the illustrated example, because the upper encoder 904 is a repetition encoder and the lower encoder 908 is a TBCC encoder, then a cyclic shift applied to the lower information sequence 910 by k bits results in a cyclically shifted encoded output sequence, by k/R. That is, the upper information sequence 906 may remain unchanged as input to the repetition encoder 904, while the lower information sequence 910 may be subjected to the described cyclic shift.

According to a further aspect of the disclosure, as long as the upper code 904 is any linear block code that exhibits a cyclic shift property, and the lower code 910 exhibits a cyclic shift property, then the overall, generalized polar code described in the present disclosure may also exhibit a cyclic shift property as described above.

In another example, the upper code 904 may be a small block code, having bit-level or multiple-bits alignment with the lower TBCC encoder 908. For example, if the code rate R for the lower TBCC encoder 908 is equal to 1/3 (i.e., R=1/3), and if the input information bits 910 are cyclic-shifted by one position (i.e., k=1), then the coded bits output from the TBCC encoder 908 are cyclic at every 3-bit level (i.e., 3k). In this example, the upper coder 904 may be a (3,2) parity code, repeated. In this way, each 3-bit unit may align with one information bit 910 input to the TBCC encoder 908.

To exploit this cyclic shift property, according to an aspect of the present disclosure, the magnitude k of the cyclic shift can be utilized to represent one or more bits of information, the information being represented by the value of k (or, in some examples, a multiple of k, or any suitable function of k). Accordingly, a receiving device may decode the received signal and determine the magnitude of the cyclic shift k of the information bits. Once the shift value k is determined, the information represented by this shift may be utilized, in addition to any information carried on the decoded input information sequence.

For example, to determine the magnitude of the cyclic shift, after decoding the received message, the receiving device 504 may determine whether an information integrity check such as a cyclic redundancy check (CRC) verifies the information as decoded. If the integrity check fails, then the receiving device may apply a cyclic shift to the received information, and once again calculate a CRC at this shift. Repeating this procedure until a shift of k indexes results in a successful CRC can confirm that the information bits received represent a cyclic shift of k indexes. Accordingly, a series of CRC hypotheses may be determined until a CRC matches the received bits. In this way, the CRC may be exploited to determine the amount of cyclic shift applied.

Some aspects of the disclosure, described further below, find particular application for millimeter-wave (mmW) communication. mmW communication generally refers to wireless communication at high bands above 24 GHz, which can provide a very large bandwidth. Such mmW signals may be highly directional narrow beam signals, and accordingly, beamforming is frequently utilized in such networks. Beamforming generally refers to directional signal transmission or reception. For a beamformed transmission, the amplitude and phase of each antenna in an array of antennas may be precoded, or controlled to create a desired (i.e., directional) pattern of constructive and destructive interference in the wavefront.

FIG. 10 is a schematic illustration of beam sweeping according to one example. As seen in this figure, a base station 1002 may provide a cell utilizing mmW signaling. In such a cell that utilizes mmW signaling, broadcast information may be transmitted a plurality of times, each broadcast transmission including a transmission index. Here, the transmission index may correspond to a beam index or a symbol index. That is, because mmW transmissions may utilize a narrow beam, a beamformed transmission of a broadcast channel (e.g., a physical broadcast channel (PBCH)) may be transmitted a plurality of times, directed to different portions of a cell, each transmission including the same or similar broadcast information, but different (e.g., sequential) transmission indexes. In this illustration, the broadcast is swept across a 180° (semi-circular) range, with four transmission indexes, labeled 1-4. By sweeping the indexed beamformed transmissions to all parts of the cell, over time, the broadcast on the PBCH can effectively reach all UEs within the cell, including UEs 1004 and 1006.

In such an example, the transmission index may correspond to k (e.g., may be equal to k, or may be any suitable function of k), which is the cyclic shift applied to the information bits. That is, information such as a beam index may be embedded in the amount of the cyclic shift. Furthermore, depending on the location of a receiving device such as the UE 1006, two or more of the encoded broadcast transmissions (e.g., having index 2 and index 3) may be received. In this example, because each sequential broadcast may be encoded with a different, sequential value of the cyclic shift k, the received signals may have different cyclic shifts. Accordingly, the receiving device 1006 may decode a plurality of sequential broadcasts, apply the reverse of the cyclic shift to align the respective transmissions, and soft combine the multiple transmissions to improve the reliability of the signals.

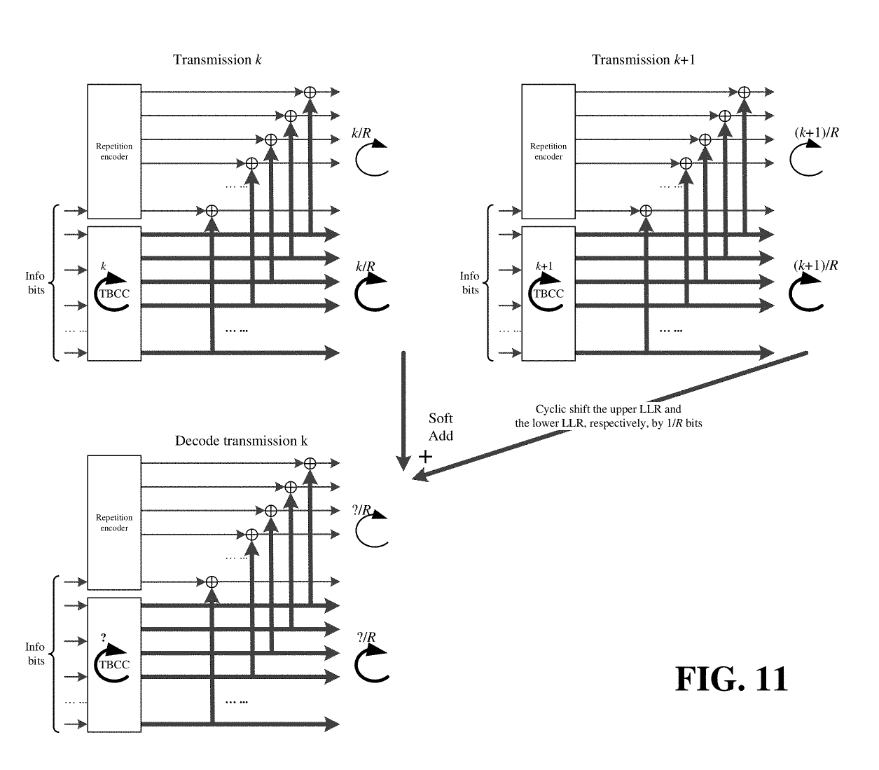

FIG. 11 is a schematic illustration showing reception of two encoded messages in sequential PBCH transmissions, having transmission indexes k and k+1, where k is unknown to the receiving device. For ease of description, the receiving device is assumed to be UE 1006 in FIG. 10, which received two sequential PBCH transmissions corresponding to transmission indexes 2 and 3. Here, the receiving device 1006 may be assumed to know that the two transmissions are sequential, such that the difference between the respective transmission indexes is 1; however, in various aspects of the disclosure, the difference need not be 1, and as long as the difference between respective transmission indexes is known to the receiving device, the same or similar algorithm described below may be applied. In this illustration, the receiving device 1006 may receive transmission k and decode the information bits utilizing the algorithm described above (e.g., see FIG. 7). Similarly, the receiving device may receive transmission k+1 and decode the information in the same way.

FIG. 12 is a flow chart illustrating an exemplary process 1200 of receiving and decoding a generalized one-step polar coded message by soft combining a plurality of such messages according to some aspects of the present disclosure. As described below, some or all illustrated features may be omitted in a particular implementation within the scope of the present disclosure, and some illustrated features may not be required for implementation of all embodiments. In some examples, the process 1200 may be carried out by the scheduling entity 300 illustrated in FIG. 3; the scheduled entity 400 illustrated in FIG. 4; the receiving device 504 illustrated in FIG. 5; the UE 1006 illustrated in FIG. 10; or any other suitable apparatus or means for carrying out the functions or algorithm described below.

At block 1202, the receiving device 504 may receive a coded transmission having transmission index k. Referring to FIG. 10, this may correspond to a beam sweeping scenario where the UE 1006 receives a PBCH broadcast with transmission index 2. Here, the receiving device 504 may determine the LLRs of received bits of the coded transmission, as described above. At block 1204, the receiving device 504 may receive a subsequent coded transmission having transmission index k+1. Referring to FIG. 10, this may correspond to a beam sweeping scenario where the UE 1006 receives a PBCH broadcast with transmission index 3. Here, the receiving device 504 may determine the LLRs of received bits of the coded transmission, as described above.

At block 1206, the receiving device 504 may apply a cyclic shift of 1/R bits to the upper bits and the lower bits, respectively, of the second transmission. As described above, because the transmission index between k and k+1 differs by 1, then the cyclic shift between coded transmissions k and k+1 differs by 1/R, the inverse of the coding rate of the TBCC coder. That is, because the receiving device 504 may know that the sequential transmissions have an incrementing cyclic shift from one transmission index to the next (i.e., from k to k+1), by virtue of the cyclic shift property of the generalized polar code, it may be inferred that sequentially received, encoded transmissions have cyclic shifts that increment according to the inverse of the code rate R of the TBCC encoder. In other words, if the cyclic shift of transmission k is equal to k/R, then the cyclic shift of transmission k+1 is equal to (k+1)/R=k/R+1/R. Thus, the difference in the cyclic shift applied to the two transmissions is 1/R. Therefore, if a cyclic shift of 1/R bits is applied to the upper bits and the lower bits, respectively, of transmission k+1, then the received, coded bits represent the same information. Therefore, by decoding both signals and combining the received energy, the reliability of the received transmission may be improved.

At block 1208, the receiving device 504 may soft-combine transmission k and the cyclic-shifted version of transmission k+1. In this example, because the transmissions at index k and k+1 may be received at different times, time diversity may be exploited to further improve the reliability of the information. That is, as illustrated in FIG. 11, after applying the cyclic shift 1/R to the upper and lower bits, respectively, of the transmission at index k+1, the received bits from the two transmissions may be soft combined (e.g., added). After soft combining, the decoding procedure described above (e.g., see FIG. 7) may be applied to decode the information bits of transmission k. For example, at block 1210, utilizing the soft-combined bits, the receiving device 504 may determine the LLRs of the upper code, and at block 1212, the receiving device 504 may decode the upper code to obtain the input bits to the upper code. Going back the other direction, at block 1214, the receiving device 504 may determine the output bits of the upper code by utilizing the encoding algorithm of the upper code (Code A). Then, at block 1216, the receiving device 504 may utilize the determined output bits of the upper code to determine the LLRs of the output bits of the lower code. At block 1218, the receiving device 504 may decode the lower code, applying the determined LLRs of the lower code's output bits to a decoding algorithm corresponding to the lower code. Thereafter, the full set of input information bits having been determined, at block 1220 the receiving device 504 may determine the value of k utilized for the cyclic shift of transmission k. That is, as described above, an embedded integrity check or CRC may be applied to a series of cyclically shifted versions of the determined input information bits to test a series of hypotheses for the value k, settling on the value of k that results in the CRC passing.

### Utilizing a Cyclic Shift-Based Encoder to Embed a Transmission Index in a Broadcast Transmission

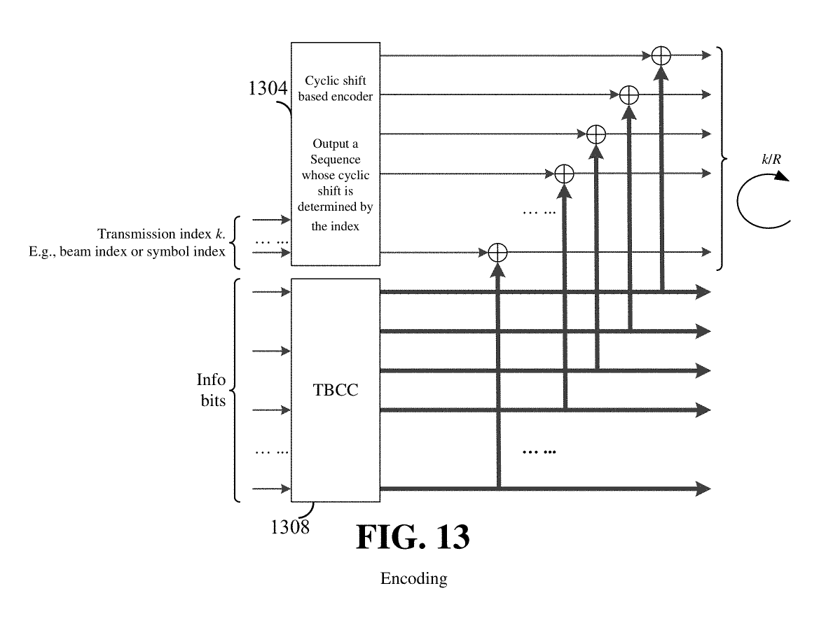

In another aspect of the disclosure, generalized polar coding may be utilized to concatenate the outputs of a cyclic-shift-based encoder and a TBCC encoder, wherein bits representing a value of a cyclic shift may be inputted into the cyclic-shift-based encoder, and information bits may be inputted into the TBCC encoder. For example, FIG. 13 illustrates an upper encoder 1304 utilizing a cyclic-shift-based encoding. The cyclic-shift-based encoder 1304 may be implemented by generating an output sequence whose cyclic shift is determined by the value of its input sequence. The default, base, or unshifted output sequence, which may be subjected to the cyclic shift, may be an m-sequence, a Costas array sequence, a sequence with one 1 and the rest of the bits being 0, or any other suitable sequence. Here, the magnitude of the cyclic shift applied to the default sequence may correspond to the value of the one or more bits of the input sequence applied to the cyclic-shift-based encoder. For example, for a two-bit input to a cyclic shift-based encoder, possible input values may be 00, 01, 10, or 11. For these respective input sequences, the output sequence may be subjected to a cyclic shift of 0, 1, 2, or 3 indexes, respectively. Of course, any suitable number of input bits may be utilized to represent the amount of cyclic shift.

Thus, in one example, the upper code 1304 may be utilized to convey transmission index information in a beam sweeping configuration as described above and illustrated in FIG. 10. Of course, the encoder described herein and utilizing the presently disclosed configuration need not be limited to such a beam sweeping configuration, and the upper code 1304 may be utilized to convey any other suitable information. Further, the lower code 1308 (e.g., utilizing TBCC encoding, as illustrated in FIG. 13) may be utilized to convey an information message, such as a broadcast channel (e.g., PBCH).

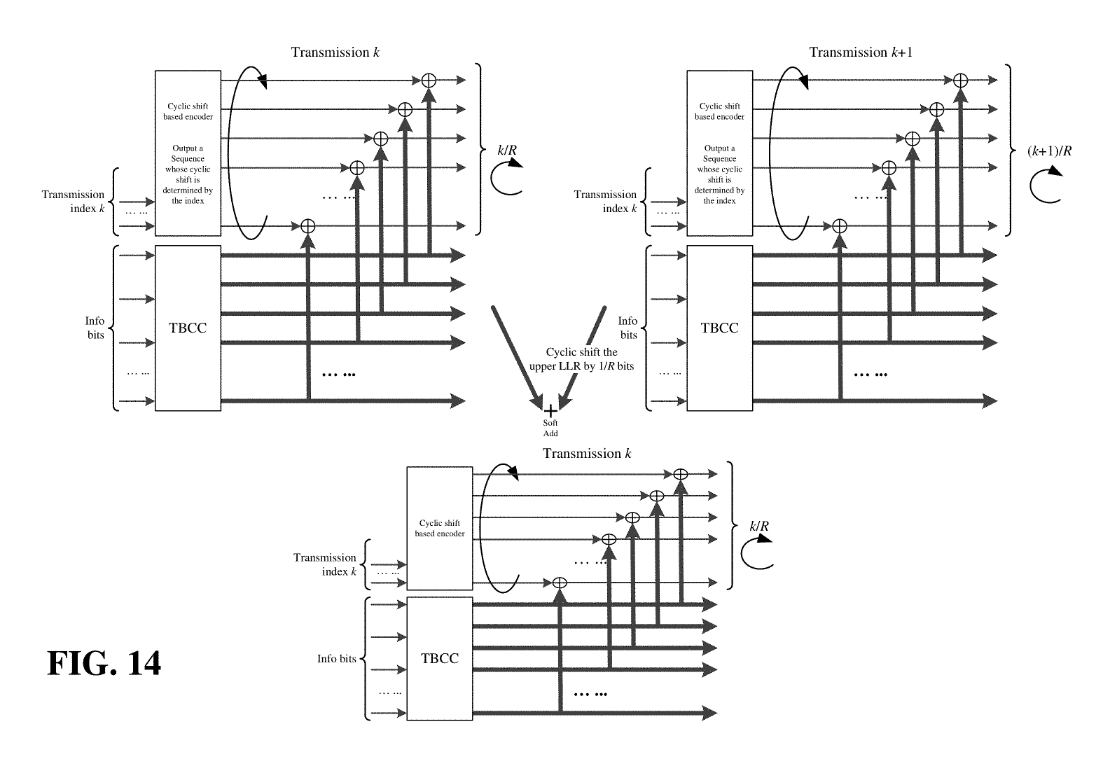

Referring now to FIG. 14, a decoding algorithm for receiving and decoding a transmission utilizing the generalized polar code of FIG. 13 is shown. Here, the generalized polar code concatenates an upper code 1304 utilizing a cyclic shift-based encoding, and a lower code 1308 utilizing TBCC encoding. As in the previous example described above and illustrated in FIGS. 10-12, a receiving device 504 may receive two sequential PBCH transmissions, having respective transmission indexes k and k+1.

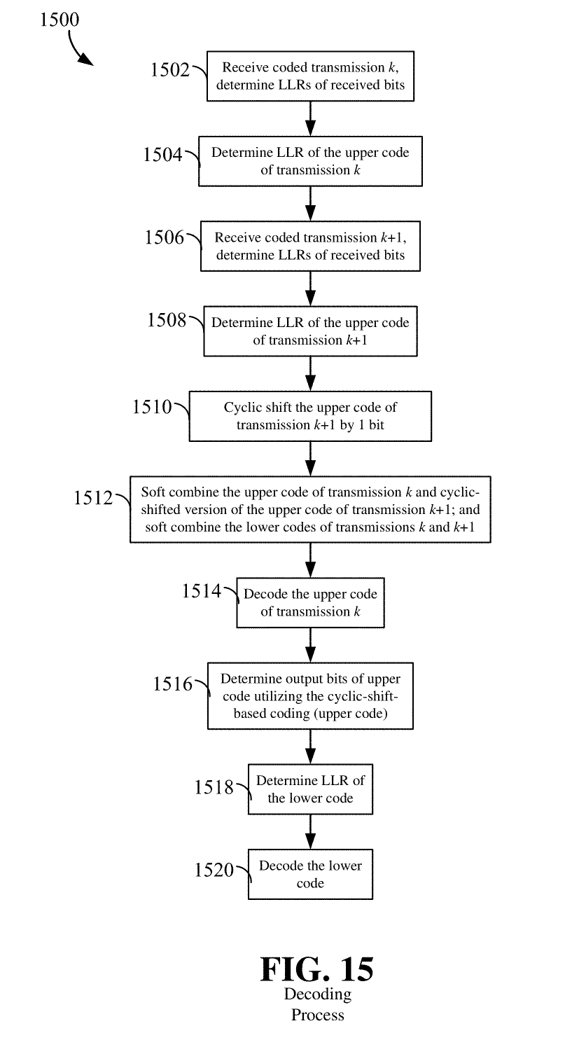

FIG. 15 is a flow chart illustrating an exemplary process 1500 of receiving and decoding a generalized one-step polar coded message by soft combining a plurality of such messages in accordance with some aspects of the present disclosure. As described below, some or all illustrated features may be omitted in a particular implementation within the scope of the present disclosure, and some illustrated features may not be required for implementation of all embodiments. In some examples, the process 1500 may be carried out by the scheduling entity 300 illustrated in FIG. 3; the scheduled entity 400 illustrated in FIG. 4; the receiving device 504 illustrated in FIG. 5; the UE 1006 illustrated in FIG. 10; or any other suitable apparatus or means for carrying out the functions or algorithm described below.

At block 1502, the receiving device 504 may receive a coded transmission having transmission index k. Referring to FIG. 10, this may correspond to a beam sweeping scenario where the UE 1006 receives a PBCH broadcast with transmission index 2. Here, the receiving device 504 may determine the LLRs of received bits of the coded transmission, as described above. At block 1504, the receiving device 504 may determine the LLRs of the upper code of the received transmission k.

At block 1506, the receiving device 504 may receive a coded transmission having transmission index k+1. Referring to FIG. 10, this may correspond to a beam sweeping scenario where the UE 1006 receives a PBCH broadcast with transmission index 3. Here, the receiving device 504 may determine the LLRs of received bits of the coded transmission, as described above. At block 1508, the receiving device 504 may determine the LLRs of the upper code of the received transmission k+1.

Referring once again to FIGS. 9 and 11, in the previous examples it may be observed that the full information bit (input bit) sequence is subjected to a cyclic shift, resulting in a cyclic shift of the entire output sequence. In this example, however, referring to FIGS. 13 and 14, the lower part (i.e., the information bits input into the lower encoder or the TBCC encoder) is not subjected to a cyclic shift. That is, in transmission k and in transmission k+1, the information bits are the same, and the output of the lower TBCC encoder is the same. On the other hand, the upper part of the input bits is not subjected to a cyclic shift, but rather, includes information bits representing the value of the cyclic shift applied to the output bits of the upper part. Therefore, in this example, the receiving device 504 can know that the received bits are a concatenation of a cyclic-shifted version of a known sequence by k or k+1 bits, and a set of information bits (e.g., from the PBCH).

Because the receiving device knows that the upper code of transmission k+1 is a cyclically shifted version of the upper code of transmission k, then at block 1510 the receiving device 504 may cyclically shift the upper code of transmission k+1 by, e.g., one bit position, such that it is known that it represents the same information as the upper code of transmission k. Accordingly, at block 1512 the receiving device 504 may then soft combine the LLRs of the upper code of transmission k, and the LLRs of the cyclically shifted version of the upper code of transmission k+1, to improve the reliability of this information based on time diversity. Similarly, the receiving device 504 may soft combine the LLRs of the lower codes of the respective transmissions, without applying a cyclic shift.

At block 1514, after the receiving device 504 has determined the LLRs of the output of the upper code, the receiving device may then decode the upper code of transmission k, and accordingly determine the information bits input to the upper coder utilizing a decoding algorithm corresponding to the cyclic-shift-based coder 1304. For example, the known base sequence of the upper code may be cyclically shifted by the amount of the determined value of the decoded input bits of the upper code. Thus, the upper information bits, which may represent a transmission index, may be obtained by observing the amount by which the known base sequence is cyclically shifted at the output of the upper coder 1304. At block 1516, the receiving device 504 may apply the determined input bits to the upper coder 1304 to determine the output bits of the upper code.

In another example, rather than carrying out the full operations of blocks 1514 and 1516, the receiving device 504 may be configured to assume the bit values of the output of the upper code are the values with the highest LLRs, and in a straightforward fashion determine if this sequence corresponds to a cyclically shifted version of the expected base sequence. That is, because the nature of the cyclic shift based upper code 1304 is simple in this example, it may not be necessary to perform the full operations of applying a decoding algorithm to the LLRs of the output bits, performing an integrity check of the input bits, and then reversing direction and determining the encoded bit values of the output bits of the upper code.

Having the output bits of the upper code, as described above, at block 1518 the receiving device 504 may then determine the LLRs of the output bits of the lower code, and accordingly, at block 1520, decode the lower code. In this way, the information bits of the PBCH transmission may be obtained with increased reliability, being based on the combined energy from successive broadcasts of the PBCH in a beam sweeping system.

Several aspects of a wireless communication network have been presented with reference to an exemplary implementation. As those skilled in the art will readily appreciate, various aspects described throughout this disclosure may be extended to other telecommunication systems, network architectures and communication standards.

By way of example, various aspects may be implemented within other systems defined by 3GPP, such as Long-Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-15 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in FIGS. 1-15 may be configured to perform one or more of the methods, features, or steps escribed herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A method of wireless communication, comprising:
generating an upper code by encoding an upper input sequence utilizing an upper encoder;
generating a lower code by encoding a lower input sequence utilizing a lower encoder, configured to utilize a different coding algorithm than the upper encoder;
concatenating the upper code and the lower code utilizing a one-step polarization code to generate a first encoded message; and
transmitting the first encoded message.

2. The method of claim 1, wherein the lower encoder comprises a tail-biting convolutional code (TBCC) encoder.

3. The method of claim 2, wherein the upper encoder comprises a repetition encoder.

4. The method of claim 1, wherein the one-step polarization code comprises a lower output sequence equivalent to the lower code, and an upper output sequence corresponding to a bitwise logical combination of the upper code and the lower code.

5. The method of claim 4, wherein the bitwise logical combination comprises an exclusive-OR (XOR) of respective bits of the upper code and the lower code.

6. The method of claim 1, wherein an information sequence comprises the lower input sequence and the upper input sequence, and wherein the method further comprises:
cyclically shifting the information sequence by k bits, wherein k corresponds to a transmission index.

7. The method of claim 6, further comprising:
incrementing k;
regenerating the upper code and the lower code based on a second cyclically shifted information sequence corresponding to the incremented value of k;
concatenating the regenerated upper code and lower code utilizing the one-step polarization code to generate a second encoded message; and
transmitting the second encoded message.

8. The method of claim 2, wherein the upper encoder comprises a cyclic shift-based encoder, the method further comprising:
applying a cyclic shift in an amount based on a value of the upper input sequence to a predetermined output sequence of the upper encoder.

9. The method of claim 8, wherein an information sequence comprises the lower input sequence provided to the lower encoder, and wherein the method further comprises:
incrementing the value of the upper input sequence;
regenerating the upper code and the lower code utilizing the one-step polarization code to generate a second encoded message; and
transmitting the second encoded message.

10. A method of wireless communication, comprising:
receiving a first encoded message comprising a first upper code and a first lower code concatenated utilizing a one-step polarization code;
demodulating symbols of the first encoded message to determine a respective log-likelihood ratio (LLR) for each of a plurality of bits of the first encoded message;
determining LLRs of bits of the first upper code based on the LLRs for the plurality of bits of the first encoded message;
decoding the first upper code based on the LLRs of the bits of the first upper code to determine an estimated upper input sequence;
determining the bits of the first upper code by encoding the estimated upper input sequence;
determining LLRs of bits of the first lower code based on the LLRs for the plurality of bits of the first encoded message and the determined bits of the first upper code; and
decoding the first lower code based on the LLRs of the bits of the first lower code to determine an estimated lower input sequence.

11. The method of claim 10, further comprising:
receiving a second encoded message comprising a second upper code and a second lower code concatenated utilizing the one-step polarization code;
demodulating symbols of the second encoded message to determine a respective LLR for each of a plurality of bits of the second encoded message; and
soft combining the LLRs for respective bits of the plurality of bits in the first and second encoded messages,
wherein the determining the LLRs of bits of the first upper code is based on the soft combined LLRs for the plurality of bits in the first and second encoded messages, and
wherein the determining the LLRs of bits of the second lower code is based on the soft combined LLRs for the plurality of bits in the first and second encoded messages.

12. The method of claim 11, wherein the first upper code and the second upper code correspond to repetition codes having repeating sequences based on their respective upper input sequences; and
wherein the method further comprises cyclically shifting the LLRs for upper bits of the second encoded message by 1/R bits, and cyclically shifting the LLRs for lower bits of the second encoded message by 1/R bits, wherein R is a code rate of the first lower code.

13. The method of claim 11, wherein the first upper code and the second upper code correspond to cyclic-shift-based codes wherein predetermined sequences are cyclically shifted in amounts based on their respective upper input sequences.

14. An apparatus configured for wireless communication, comprising:
a processor;
a memory communicatively coupled to the processor; and
a transceiver communicatively coupled to the processor,
wherein the transceiver is configured to receive a first encoded message comprising a first upper code and a first lower code concatenated utilizing a one-step polarization code; and
wherein the processor is configured to:
demodulate symbols of the first encoded message to determine a respective log-likelihood ratio (LLR) for each of a plurality of bits of the first encoded message;
determine LLRs of bits of the first upper code based on the LLRs for the plurality of bits of the first encoded message;
decode the first upper code based on the LLRs of the bits of the first upper code to determine an estimated upper input sequence;
determine the bits of the first upper code by encoding the estimated upper input sequence;
determine LLRs of bits of the first lower code based on the LLRs for the plurality of bits of the first encoded message and the determined bits of the first upper code; and
decode the first lower code based on the LLRs of the bits of the first lower code to determine an estimated lower input sequence.

15. The apparatus of claim 14, wherein the transceiver is configured to receive a second encoded message comprising a second upper code and a second lower code concatenated utilizing the one-step polarization code; and
wherein the processor is further configured to:
utilize the transceiver to demodulate symbols of the second encoded message to determine a respective LLR for each of a plurality of bits of the second encoded message; and
utilize the transceiver to soft combine the LLRs for respective bits of the plurality of bits in the first and second encoded messages,
wherein the determining the LLRs of bits of the first upper code is based on the soft combined LLRs for the plurality of bits in the first and second encoded messages, and
wherein the determining the LLRs of bits of the second lower code is based on the soft combined LLRs for the plurality of bits in the first and second encoded messages.

16. The apparatus of claim 15, wherein the first upper code and the second upper code correspond to repetition codes having repeating sequences based on their respective upper input sequences; and
wherein the processor is further configured to cyclically shift the LLRs for upper bits of the second encoded message by 1/R bits, and to cyclically shift the LLRs for lower bits of the second encoded message by 1/R bits, wherein R is a code rate of the first lower code.

17. The apparatus of claim 15, wherein the first upper code and the second upper code correspond to cyclic-shift-based codes wherein predetermined sequences are cyclically shifted in amounts based on their respective upper input sequences.

18. An encoding apparatus comprising:
a repetition encoder configured for generating a repetition code based on one or more first input bits;
a tail biting convolutional encoder configured for generating a lower code based on one or more second input bits, wherein an input information sequence comprises the one or more first input bits concatenated with the one or more second input bits; and
a one-step polarization encoder circuit configured for concatenating a bitwise logical combination of the repetition code and the lower code, with the lower code.

19. The encoding apparatus of claim 18, wherein a cyclic shift of the input information sequence is configured to indicate a transmission index of a transmission of the input information sequence.
